(19) United States
(12) Patent Application Publication
(10) Pub. No.: US 2002/0171147 A1
(43) Pub. Date: Nov. 21, 2002

(54) Structure of a dual damascene via

(76) Inventors: Tri-Rung Yew, Hsin-Chu (TW); Kun-Chih Wang, Hsin-Chu City (TW); Yu-Sheng Yen, Miaoli City (TW)

Correspondence Address: POWELL, GOLDSTEIN, FRAZER & MURPHY LLP, P.O. BOX 97223, WASHINGTON, DC, 20090-7223, US

(21) Appl. No.: 09/854,961

(22) Filed: May 15, 2001

(51) Int. Cl. H01L 23/48

(52) U.S. Cl. 257/751; 257/774; 257/754

(57) ABSTRACT

This invention relates to a structure of a dual damascene, in particular to a structure of a dual damascene using in a via. The structure of this dual damascene via comprises of; the first gap, the second gap, the third gap, a barrier layer, the first conductive layer, the second conductive layer, the first dielectric barrier cap, the second dielectric barrier cap, the first low dielectric constant (k) dielectric layer, and the second low dielectric constant dielectric layer. The structure of the present invention can obtain better electromigration (EM) resistance and better via resistance stability by using the third gap to be situated in the first conductive layer.

### BACKGROUND OF THE INVENTION

1. Field of the Invention

This invention relates to a structure of a dual damascene, in particular, to a structure of a dual damascene used in a via. The structure of the present invention can obtain better electromigration resistance and better via resistance stability by using the over-etching method to make the bottom of the via extend to the inside of the first conductive layer.

2. Description of the Prior Art

In the manufacturing of devices on a semiconductor wafer, it is now the practice to fabricate multiple levels of conductive (typically metal) layers above a substrate. The multiple metallization layers are employed in order to accommodate higher densities as device dimensions shrink well below the one-micron design rules. Likewise, the size of inter-connective structures will also need to shrink, in order to accommodate the smaller dimensions. Thus, as integrated circuit technology advances into the sub-0.25 micron range, more advanced inter-connective architecture and new materials are required.

One such architecture is a dual damascene integration scheme in which a dual damascene structure is employed. The dual damascene process offers the advantage in process simplification by reducing the process steps required to form the vias and trenches for a given metallization level. The openings, for the wiring of a metallization level and the underlying via connecting the wiring to a lower metallization level, are formed at the same time. The procedure provides an advantage in lithography and allows for improved critical dimension control. Subsequently, both the via and the trench can be filled utilizing the same metal-filling step, thereby reducing the number of processing steps required. Because of the simplicity of the dual damascene process, newer materials can cost-effectively replace the use of the existing aluminum (Al)/SiO₂ (silicon dioxide) scheme.

One such newer material is copper. The use of copper metallization improves performance and reliability over aluminum, but copper introduces additional problems that are difficult to overcome when using known techniques for aluminum. For example, in conventional aluminum inter-connective structures, a barrier layer is usually not required between the aluminum metal line and an SiO₂ inter-level dielectric (ILD). However, when copper is utilized, copper must be encapsulated from the surrounding ILD, since copper diffuses/drifts easily into the adjoining dielectric. Once the copper reaches the silicon substrate, it will significantly degrade the device's performance.

In order to encapsulate copper, a barrier layer of some sort is required to separate the copper from the adjacent material(s). Because copper encapsulation is a necessary step requiring a presence of a barrier material to separate the copper, other materials can now be substituted for the SiO₂ as the material for ILD. Replacing the SiO₂ by a low-dielectric constant material reduces the interline capacitance, thereby reducing the resistance capacitance (RC) delay, cross-talk noise and power dissipation in the inter-connective place. However, it is generally necessary to have a barrier (or liner) present between the inter-connective place and the low dielectric constant ILD to prevent possible interaction between the inter-connective place and the low-dielectric constant ILD and also to provide adhesion between them. This barrier is desirable even when aluminum is utilized for the inter-connective place.

Referring to FIG. 1, this is the way in forming the traditional structure of the via by using the traditional method. At first, the first metal layer 10 is provided in the substrate 11. The material of this first metal layer 10 is aluminum or copper. The first barrier layer 12 is surrounding the sidewalls and at the bottom of the first metal layer 10. Then the first dielectric barrier cap 13 is formed on the first metal layer 10, the first barrier layer 12, and the substrate. The function of the first metal layer 10 is to conduct the current to bring the efficiency of the semiconductor device into full play. The function of the first barrier layer 12 and the first dielectric barrier cap 13 is to avoid the metal ions which are in the first metal layer 10 moving to another place by actions in diffusion and drift to reduce the efficiency of the first metal layer 10.

Referring to FIG. 2, the first low dielectric constant dielectric layer 14 is formed on the first dielectric barrier cap 13 and the substrate. Then a stop layer 15 and the second low dielectric constant dielectric layer 18 are formed on the first low dielectric constant dielectric layer 14. The partial first low dielectric constant dielectric layer 14, the partial second low dielectric constant dielectric layer 18, the partial stop layer 15, and the partial first dielectric barrier cap 13 are removed by using the photolithography and the etching process to form the first trench 25 and the second trench 24 in the second low dielectric constant dielectric layer 18 and the first low dielectric constant dielectric layer 14. The objective of the first low dielectric constant dielectric layer 14 and the second low dielectric constant dielectric layer 18 are to separate the first metal layer 10 from other metal layers. This condition prevents a leakage defect in the semiconductor device. The objective of the stop layer 15 is to determine the progress and the position of the etching in the etching process. In order to simplify the steps of the process, the stop layer 15 is usually ignored following the needs of the process.

Referring to FIG. 3, the second barrier layer 28 is formed on the sidewalls and at the bottom of the first trench 25 and the second trench 24. The second metal is filled into the first trench 25 and the second trench 24 to become the second metal layer 29. This second metal layer 29 is a via to connect the first metal layer 10 and other metal layers. When the current is conducted, the first metal layer can connect with other metal layers by using the second metal layer 29 to form a current circuit and to bring the efficiency of the semiconductor device into full play. The function of the second barrier layer 28 is to avoid movement of the metal ions by way of diffusion and drift in the second metal layer 29 to the surrounding first low dielectric constant dielectric layer 14 and second low dielectric constant dielectric layer 18. This will cause a broken circuit condition in the second metal layer 29. This broken circuit condition will affect the quality of the semiconductor device. The material of the second metal layer 29 is usually aluminum or copper.

Referring to FIG. 4, after polishing the second metal layer 29 which is deposited over the second dielectric barrier cap 34 on the second metal layer 29, the second barrier layer 28, and the second low dielectric constant dielectric layer. This is the traditional structure of the via. The function of the second dielectric barrier cap 34 is to prevent the metal ions in the second metal layer 29 from moving to other regions by way of diffusion and drift. This causes a brake in the circuit on the second metal layer 29, therefore the broken circuit condition will affect the quality of the semiconductor device.

In the traditional structure of the via, there is a defect at the bottom of the second trench 24. There exists a region that combines three different layers on both sides at the bottom of the second trench 24. The three different layers are the first low dielectric constant dielectric layer 14, the first dielectric barrier cap 13, and the second barrier layer 28. The materials of these three layers are different and the thermal expanding constant of the layers is not the same. When different kinds of materials are combined and each has its own thermal-expanding constant, stress will occur in the concentrated area resulting in a cracking defect. Again this is due to the different expanding degree when the different materials are heated. When the current is conducted, the materials within the semiconductor will experience an expanding condition. Stress will occur in the region that combines three different kinds of materials 30 on both sides at the bottom of the second trench 24. This concentration will further cause a cracking defect because of the different expanding degrees of the three different kinds of materials. The metal ions in the second metal layer 29 move to another place from this region by way of diffusion and drift. This will cause an electromigration failure in the second metal layer 29 and affects the via resistance stability of the second metal layer 29. This defect will also cause a broken circuit condition in the second metal layer 29 and make the second metal layer 29 loose its inter-connective function. This defect will further affect the qualities of the semiconductor device. Therefore, the structure of the dual damascene via in the present invention will solve the problem produced from this defect.

### SUMMARY OF THE INVENTION

In accordance with the background of the above-mentioned invention, when a traditional structure of the via is used a cracking defect will occur within the region that combines three different kinds of layers. This is a result of the three different layers having different expanding degrees among the three layers due to a different thermal expanding constant. These three different kinds of layers are low dielectric constant dielectric layer, dielectric barrier cap, and barrier layer. This cracking defect will cause the electromigration fail in the via and to affect the via resistance stability of the via. The main objective of the invention is to provide a structure of a via that avoids a cracking defect within the region that combines three different thermal expanding constant materials by using the over-etching method to make the bottom of the via extend to the inside of the first conductive layer.

The second objective of this invention is to get better electromigration resistance by using the over-etching method to make the bottom of the via extend to the inside of the first conductive layer.

The third objective of this invention is to get better via resistance stability by using the over-etching method to make the bottom of the via extend to the inside of the first conductive layer.

The further objective of this invention is to increase the qualities of the semiconductor devices by using the over-etching method to make the bottom of the via extend to the inside of the first conductive layer.

In according to the foregoing objectives, the present invention provides a structure of a via to avoid the cracking defect within the region that combines three different thermal expanding constant materials. This is achieved by using the over-etching method to make the bottom of the via extend to the inside of the first conductive layer. The structure of the via in the present invention can get better electromigration resistance and better via resistance stability. The present invention can further increase the qualities of the semiconductor devices by reducing the cracking defect.

### BRIEF DESCRIPTION OF THE DRAWINGS

In the accompanying drawing forming a material part of this description, there is shown:

FIG. 1 shows a diagram in forming the first metal layer and the first dielectric barrier cap on the substrate and forming the first barrier layer on the sidewalls and at the bottom of the first metal layer;

FIG. 2 shows a diagram in forming the first low dielectric constant dielectric layer, a stop layer, and the second low dielectric constant dielectric layer on the first dielectric barrier cap and forming the first trench and the second trench;

FIG. 3 shows a diagram in forming the second barrier layer on the sidewalls and at the bottom of the first trench and the second trench and filling the first trench and the second trench with the second metal material;

FIG. 4 shows a diagram in removing the second metal layer which is over deposited and forming the second dielectric barrier cap on the second low dielectric constant dielectric layer, the second barrier layer, and the second metal layer;

FIG. 5 shows a diagram in forming the first conductive layer on the substrate and forming the first barrier layer on the sidewalls and at the bottom of the first conductive layer;

FIG. 6 shows a diagram in forming the first dielectric barrier cap on the substrate, the first barrier layer, and the first conductive layer;

FIG. 7 shows a diagram in forming the first low dielectric constant dielectric layer and the first stop layer on the first dielectric barrier cap;

FIG. 8 shows a diagram in forming a photoresist layer on the first stop layer after deciding the location of the via;

FIG. 9 shows a diagram in etching the partial first stop layer to form a breach and removing the photoresist layer;

FIG. 10 shows a diagram in forming the second low dielectric constant dielectric layer and the second stop layer on the first stop layer and the first low dielectric constant dielectric layer;

FIG. 11 shows a diagram in forming a photoresist layer on the second stop layer after deciding the location and dimension of the via;

FIG. 12 shows a diagram in etching the partial second stop layer and removing the photoresist layer;

FIG. 13 shows a diagram in forming the first gap in the second low dielectric constant dielectric layer and the second stop layer and forming the second gap in the first low dielectric constant dielectric layer and the first stop layer;

FIG. 14 shows a diagram in forming the third gap in the first conductive layer and the first dielectric barrier cap and removing the partial first stop layer;

FIG. 15 shows a diagram in forming the second barrier layer on the sidewalls and at the bottom of the first gap, the second gap, and the third gap and removing the second stop layer;

FIG. 16 shows a diagram in filling the first gap, the second gap, and the third gap with the second conductive material to form the second conductive layer;

FIG. 17 shows a diagram in removing the second conductive layer which is over deposited and forming the second dielectric barrier cap on the second low dielectric constant dielectric layer, the second barrier layer, and the second conductive layer; and

FIG. 18 shows a diagram in adding the third barrier layer in the via in the structure of the via.

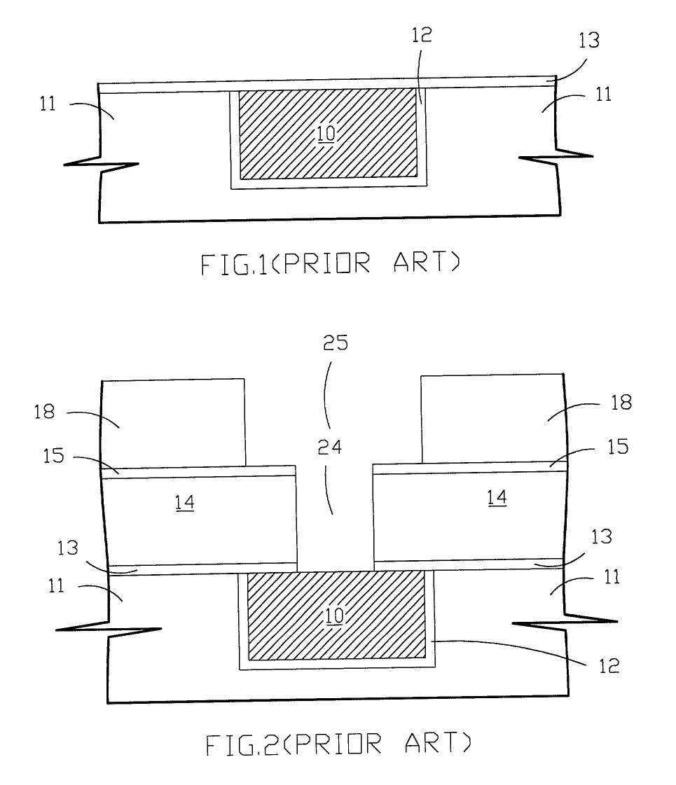

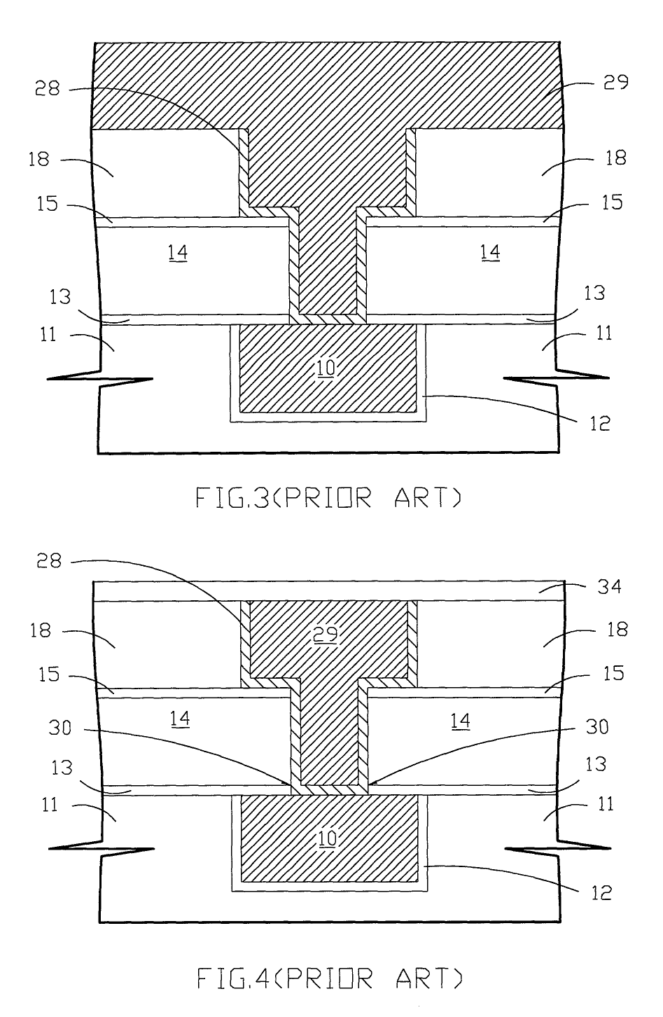

### DESCRIPTION OF THE PREFERRED EMBODIMENT

The foregoing aspects and many of the intended advantages of this invention will become more readily appreciated as the same becomes better understood by reference to the following detailed description, when taken in conjunction with the accompanying drawings, wherein:

The emphasis of the present invention is the structure of the via. There are a lot of methods in forming this kind of the via structure. The method, which is used in the following embodiment, is one of the methods and does not limit the range of the present invention. Referring to FIG. 5, the first conductive layer 100 is provided in the substrate 110 at first. The material of the first conductive layer 100 comprises a conductive material which can be of any of a variety of materials used for forming interconnects on a semiconductor wafer, such as a silicon wafer.

Typically, a metal, such as aluminum (Al), aluminum alloy, copper (Cu), or copper alloy, are used when forming the first conductive layer 100 on a wafer. The first barrier layer 120 is formed on the sidewalls and at the bottom of the first conductive layer 100. The function of the first conductive layer 100 is to conduct the current to bring the efficiency of the semiconductor device into full play. The function of the first barrier layer 120 is to avoid the metal ions which are in the first conductive layer 100 moving to another place by actions in diffusion and drift to reduce the efficiency of the first conductive layer 100. A material, which comprises tantalum nitride (TaN), titanium nitride (TiN) or tantalum, is most used to be the material of the first barrier layer 120. The different thickness of the first barrier layer 120 is usually following the needs of the process. The thickness of the first barrier layer is usually about 10 to 500 angstroms.

In the traditional technology, aluminum or its alloy is usually used to be the material of the conductive layer. In the present technology, copper and its alloy are used as the material of the conductive layer to gradually replace aluminum and its alloy. Because copper has a higher resistance to electromigration and lower electrical resistivity than aluminum, it is a preferred material for inter-connective wiring. In addition, copper has lower resistivity than aluminum, making copper a desirable metal for use in forming plugs. However, because of its diffusion property in the dielectric material and incompatibility with silicon materials, copper requires encapsulation to isolate it from most adjacent materials.

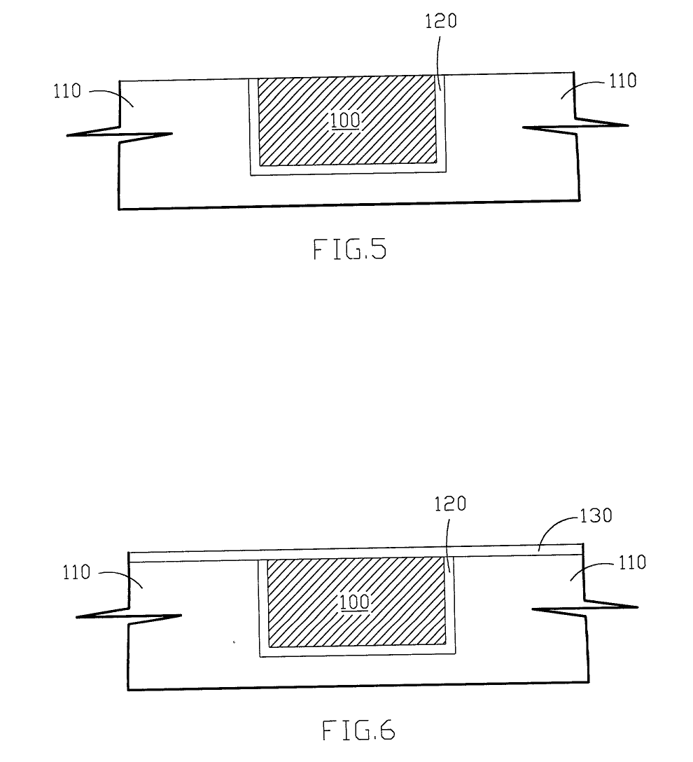

Referring to FIG. 6, the first dielectric barrier cap 130 is formed on the first conductive layer 100, the first barrier layer 120, and the substrate 110. The function of the first dielectric barrier cap 130 is to avoid movement of the metal ions in the first conductive layer 100 by way of diffusion and drift thus reducing the efficiency of the first conductive layer 100. Silicon nitride (SiN) or silicon carbide (SiC) is the preferred used material of the first dielectric barrier cap 130. The different thickness' of the first dielectric barrier cap 130 is usually determined by the needs of the process. The thickness of the first dielectric barrier cap 130 is usually about 100 to 1000 angstroms.

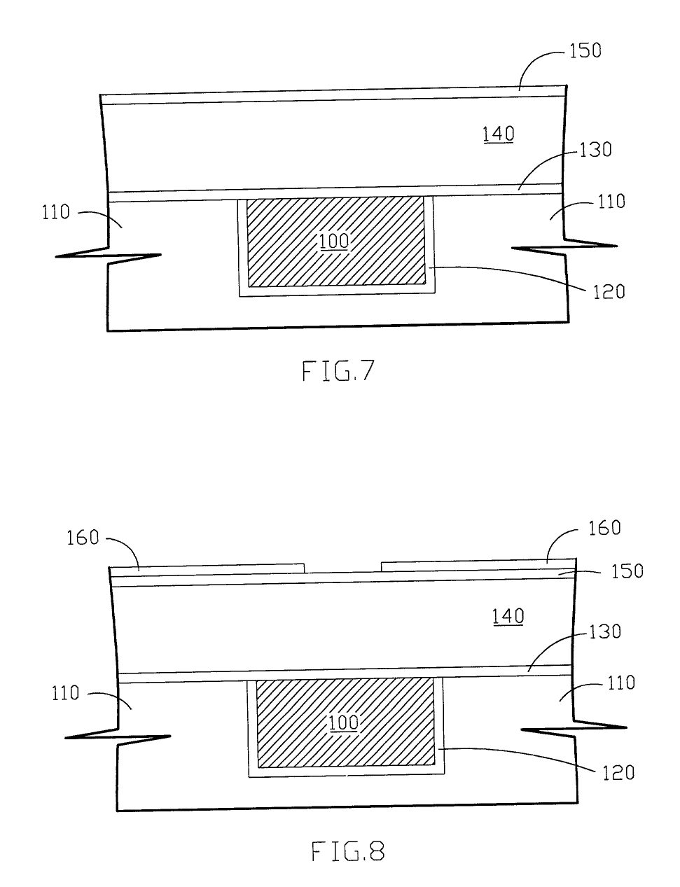

Referring to FIG. 7, the first low dielectric constant dielectric layer 140 is formed on the first dielectric barrier cap 130, and the first stop layer is formed on the first low dielectric constant dielectric layer. The objective of the first low dielectric constant dielectric layer 140 is to separate the first conductive layer 100 from other conductive layers. This condition can conduct the current from the first conductive layer to other conductive layers by using the channel, which is designed to prevent a leakage defect in the semiconductor device. Modified silicon dioxide or organic material is usually used in the first low dielectric constant dielectric layer 140, such as fluorinated oxide, SILK, coral, back diamond, or polyimide. Fluorinated oxide is a chemical composition that is produced by adding limited fluorine (F) to silicon dioxide. The objective of the first stop layer 150 is to determine the progress and the position in the etching process. Silicon nitride, silicon carbide, or silicon oxynitride is used most as the material of the first stop layer 150. The different thickness' of the first stop layer 150 is usually determined by the needs of the process. The thickness of the first stop layer 150 is usually about 100 to 1000 angstroms. In order to simplify the steps and increase the efficiency of the process, the first stop layer 150 is usually ignored following the needs of the process. The first stop layer 150 is still used in the embodiment, but this description can not limit the range of the present invention.

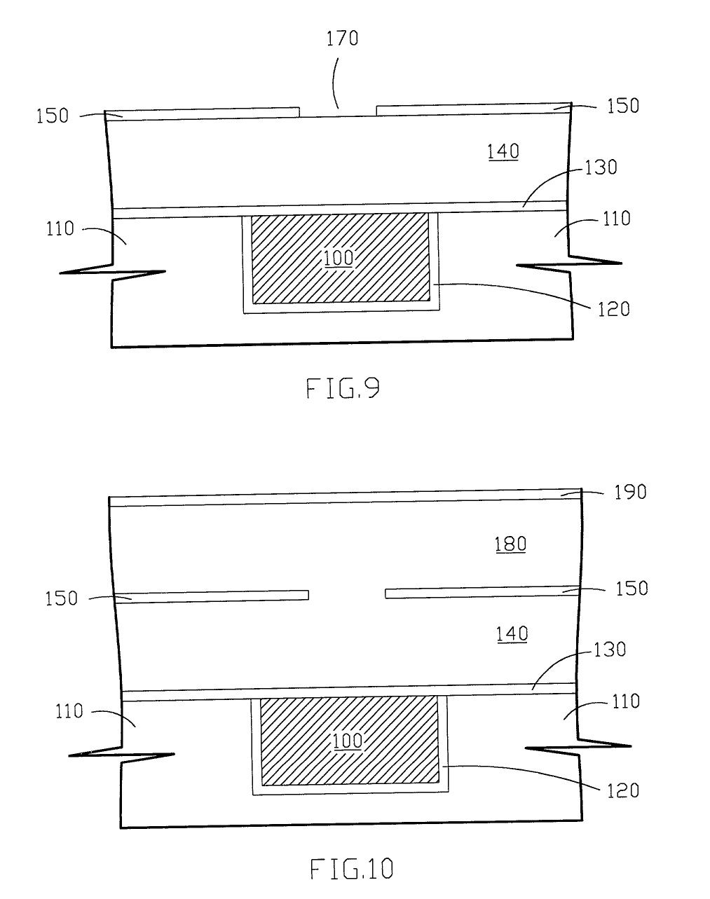

Referring to FIG. 8, after deciding the location of the via, a first photoresist layer 160 is formed on the partial first stop layer 150. Referring to FIG. 9, after etching the partial first stop layer 150, a breach 170 is formed in the first stop layer 150. The bottom of this breach 170 shows the first low dielectric constant dielectric layer. Then the first photoresist layer 160 is removed.

Referring to FIG. 10, the second low dielectric constant dielectric layer 180 is formed on the first stop layer 150 and the first low dielectric constant dielectric layer 140 and the breach 170 is filled. Then the second stop layer 190 is formed on the second low dielectric constant dielectric layer 180. The objective of the second low dielectric constant dielectric layer 180 is to separate the first conductive layer 100 from other conductive layers. This condition can conduct the current from the first conductive layer to other conductive layers by using the designed channel to prevent the leakage defect in the semiconductor device. Modified silicon dioxide or organic material are usually used as the material of the second low dielectric constant dielectric layer 180, such as fluorinated oxide, SILK, coral, back diamond, or polyimide. Fluorinated oxide is a chemical composition that is produced by adding limited fluorine to silicon dioxide. The objective of the second stop layer 190 is to determine the progress and the position in the etching process. Silicon nitride, silicon carbide, or silicon oxynitride is most widely used material of the second stop layer 190. The different thickness' of the second stop layer 190 is usually determined by the needs of the process. The thickness of the second stop layer 190 is usually about 100 to 1000 angstroms. In order to simplify the steps and increase efficiency of the process, the second stop layer 190 is usually ignored following the needs of the process. The second stop layer 190 is still used in the embodiment, but this description can not limit the range of the present invention

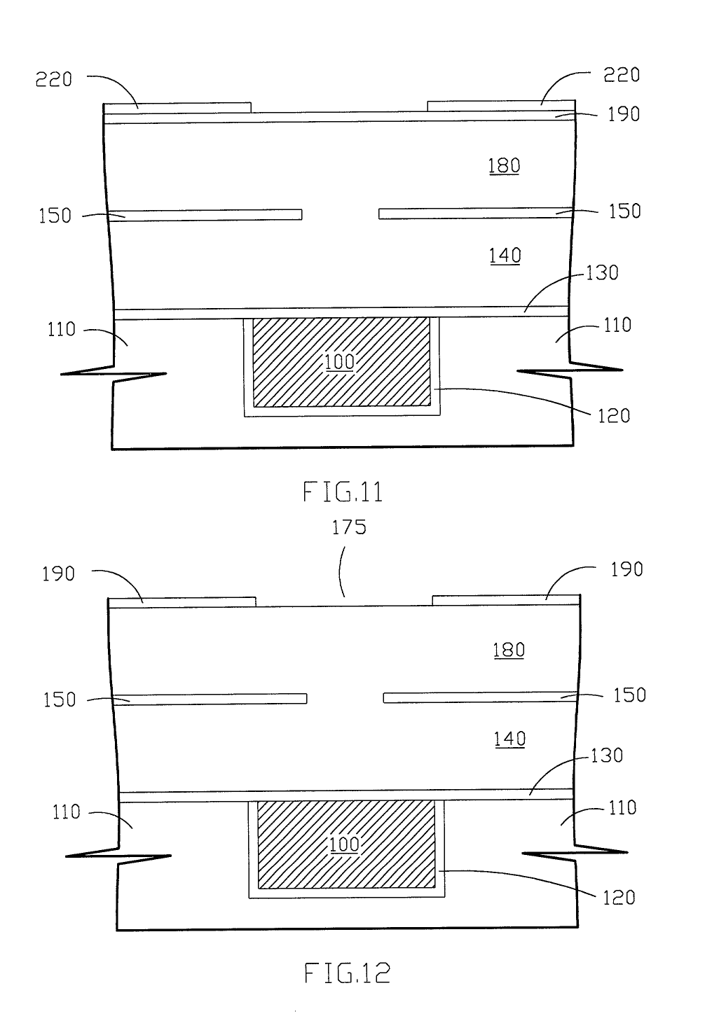

Referring to FIG. 11, after deciding the location and the dimension of the via the second photoresist layer 220 is formed on the partial second stop layer 190. Referring to FIG. 12, after etching the partial second stop layer 190, a breach 175 is formed in the second stop layer 190. The bottom of the breach 175 shows the second low dielectric constant dielectric layer 180. Then the second photoresist layer 220 is removed.

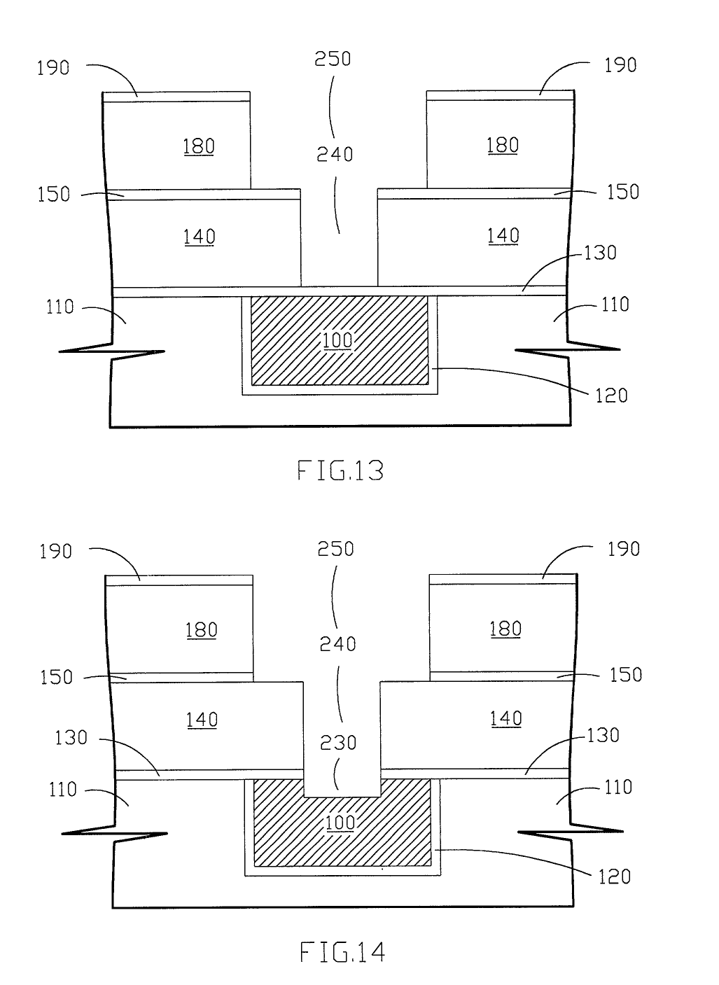

Referring to FIG. 13, the partial first low dielectric constant dielectric layer 140 and the partial second low dielectric constant dielectric layer 180 are removed in the etching process to form the first gap 250 in the second low dielectric constant dielectric layer 180 and the second stop layer 190 and to form the second gap 240 in the first low dielectric constant dielectric layer 140 and the first stop layer 150. The inside of the first gap 250 and the second gap 240 communicate with each other. The partial bottom of the first gap 250 shows the first stop layer and the bottom of the second gap 240 shows the first dielectric barrier cap 130. Because there are the first stop layer 150 and the second stop layer 190 on the first low dielectric constant dielectric layer 140 and the second low dielectric constant dielectric layer 180 individually to be the barrier layer. Therefore, the channel will be formed by etching the partial first low dielectric constant dielectric layer 140 and the partial second low dielectric constant dielectric layer 180 which are in the plan and other region of the first low dielectric constant dielectric layer 140 and the second low dielectric constant dielectric layer 180 will not be etched.

Referring to FIG. 14, after forming the first gap 250 in the second low dielectric constant dielectric layer 180 and the second stop layer 190 and forming the second gap 240 in the first low dielectric constant dielectric layer 140 and the first stop layer 150, the etching process continues to proceed. In the traditional process to form the traditional via structure, the etching process is stopped after forming the first gap 250 and the second gap 240. Therefore, this continuing etching process compared with the traditional etching process is called over-etching process. The partial first dielectric barrier cap 130 and the partial first conductive layer 100 is removed by adjusting the etching selection rate to form the third gap 230 in the first dielectric barrier cap 130 and the first conductive layer 100. The inside of the third gap 230 and the second gap 240 communicates with each other and the bottom of the third gap 230 shows the first conductive layer 100. The depth of the third gap 230 in the first conductive layer 100 is about 100 to 2000 angstroms. The first gap 250, the second gap 240, and the third gap 230 are combined to become the shape of the via. The partial first stop layer 150 is removed to show the first low dielectric constant dielectric layer 140 at the partial bottom of the first gap 250 in the etching process.

Referring to FIG. 15, after removing the second stop layer 190 (the second stop layer 190 can still be retained), the second barrier layer 280 is formed on the sidewalls of the first gap 250, the second gap 240, and the third gap 230 and at the partial bottom of the first gap 250 (and on the second stop layer 190). Following the needs of efficiency, sometimes the second barrier layer 280 which is at the bottom of the third gap 230 will be removed to make the semiconductor device reach maximum efficiency. A material, which comprises tantalum nitride, titanium nitride or tantalum, is most used to be the material of the second barrier layer 280. The different thickness' of the second barrier layer 280 is usually determined by the needs of the process. The thickness of the second barrier layer 280 is usually about 10 to 500 angstroms. Following the needs of the process, the second barrier layer 280 which is at the bottom of the third gap 230 can be removed to keep better adhesion ability and to keep better electro-migration ability.

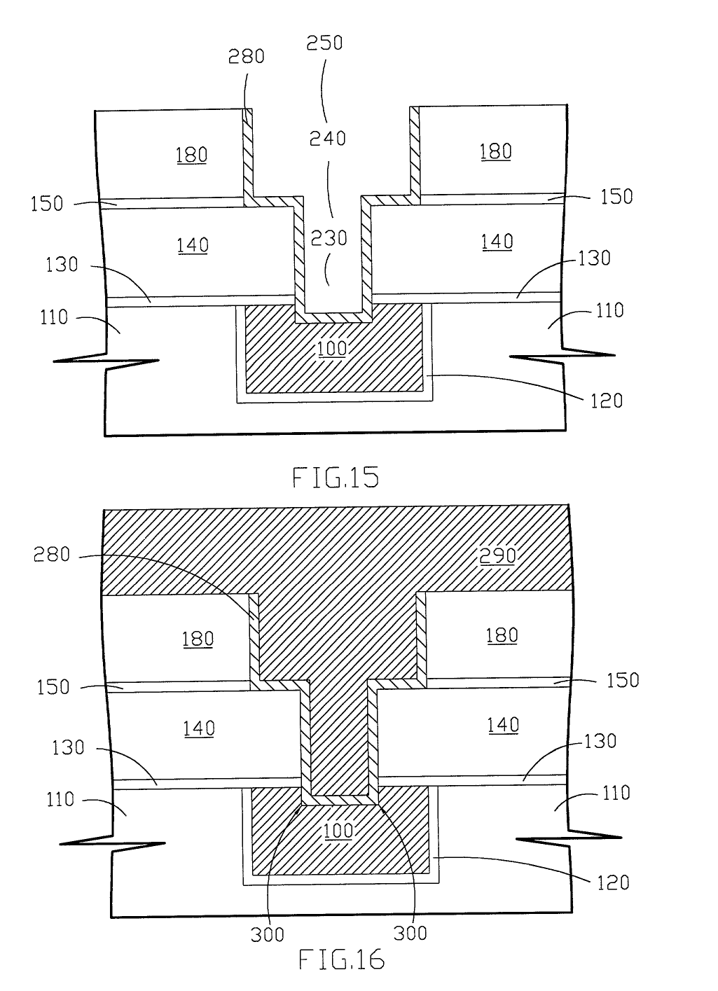

Referring to FIG. 16, filling a conductive material into the first gap 250, the second gap 240, and the third to form the second conductive layer 290. The second conductive layer 290 is the via to connect the first metal layer 10 and other metal layers. When the current is conducted, the first metal layer can connect with other metal layers by using the second metal layer 29 to form a current circuit and to bring the efficiency of the semiconductor device into full play. The function of the second barrier layer 280 is to avoid movement of the metal ions in the second conductive layer 290 to the surrounding first low dielectric constant dielectric layer 140 and second low dielectric constant dielectric layer 180; by way of diffusion and drift. Thus a broken circuit condition in the second conductive layer 290 will occur. This broken circuit condition will affect the quality of the semiconductor device. When the current is conducted, the interface between the second barrier layer 280 and the first low dielectric constant dielectric layer 140 and the interface between the second barrier layer 280 and the second low dielectric constant dielectric layer 180 will cause higher resistance, the interface between the second barrier layer 280 and the first conductive layer 100 will result in lower resistance. Therefore, the barrier layer 280 at the bottom of the third gap 230 will not hold back the ions movement between the first conductive layer 100 and the second conductive layer 290. Following the differences of the process, the second barrier layer 280 which is at the bottom of the third gap 230 can be removed to make better adhesion ability between the second conductive layer 290 and the first conductive layer 100, to decrease the resistance, and to keep better electro-migration ability.

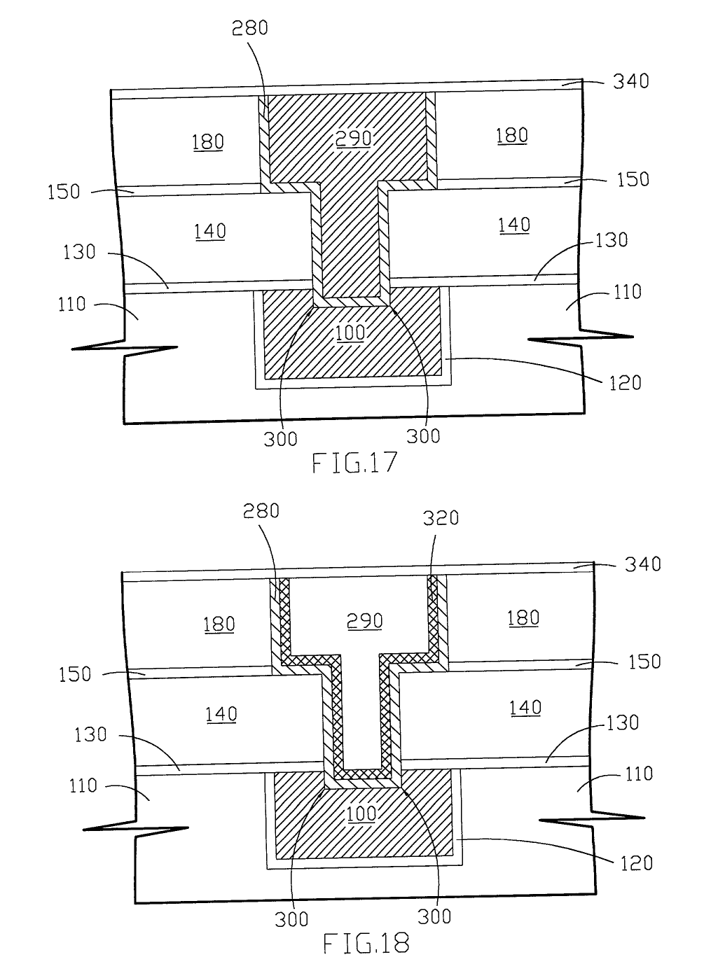

Referring to FIG. 17, the second conductive layer 290 is removed. The chemical mechanical polishing (CMP) method is usually used to remove the second conductive layer 290. Then the second dielectric barrier cap 340 is formed on the second low dielectric constant dielectric layer 180, the second barrier layer 280, and the second conductive layer 290 that completes the structure of the dual damascene via. The function of the second dielectric barrier cap 340 is to avoid movement of the metal ions in the second conductive layer 290 to another location by way of diffusion and drift resulting in reduced efficiency of the second conductive layer 290. Silicon nitride or silicon carbide is the most used material of the second dielectric barrier cap 340. The different thickness of the second dielectric barrier cap 340 is usually determined by the needs of the process. The thickness of the second dielectric barrier cap 340 is usually about 100 to 1000 angstroms.

Referring to FIG. 18, in order to increase the adhesion force between the second barrier layer 280 and the second conductive layer 290, the third barrier layer 320 is formed on the sidewalls of the first gap 250, the second gap 240, and the third gap 230, at the bottom of the third gap 240, and at the partial bottom of the first gap after forming the second barrier layer 280 following the needs of the process. The third barrier layer 320 is on the second barrier layer 280. Then the second conductive layer 290 is formed to complete the structure of the dual damascene via. The function of the third barrier layer 320 is to increase the adhesion force between the second barrier layer 280 and the second conductive layer 290 and to avoid the leakage defect. Following the different needs of the products' efficiency, the second barrier layer 280 which is at the bottom of the third gap 230 will be removed to make the semiconductor device reach to its efficiency, such as lower resistance and lower resisting electro-migration ability. Tantalum is most used to be the material of the third barrier layer 320. The different thickness of the third barrier layer 320 is usually following the needs of the process. The thickness of the third barrier layer 320 is usually about 10 to 500 angstroms.

In the structure of the present invention of the via, the bottom of the via will extend to the first conductive layer by using an over-etching method to avoid the cracking defect in the region that combines three different thermal expanding constant materials by using the over-etching method to make the bottom of the via extend to the inside of the first conductive layer. Although both sides at the bottom of the via can easily cause the cracking defect. But the bottom of the via is situated in the first conductive layer. The leakage defect will not affect the efficiency of the semiconductor device at the bottom of the via.

In accordance with the present invention, the present invention provides a structure of a via that avoids the cracking defect in the region that combines three different thermal expanding constant materials by using the over-etching method to make the bottom of the via extend to the inside of the first conductive layer. The structure of the via in the present invention results in better electromigration resistance and better via resistance stability. The present invention can further increase the qualities of the semiconductor devices by reducing the cracking defect.

Although specific embodiments have been illustrated and described, it will be obvious to those skilled in the art that various modifications may be made without departing from what is intended to be limited solely by the appended claims.

What is claimed is:

1. a means of a dual damascene via, said structure comprises:
a first conductive layer, said conductive layer being located in a substrate;
a first barrier layer, said first barrier layer being located on a sidewall and a bottom of said first conductive layer to prevent a first ion which is in said first conductive layer moving out from said first conductive layer;
a first low dielectric constant dielectric layer, said first low dielectric constant dielectric layer being located on said substrate, said first barrier layer, and said first conductive layer to isolate said first conductive layer;
a first dielectric barrier cap, said first dielectric barrier cap being located at said first low dielectric constant dielectric layer to prevent said first ion which is in said first conductive layer moving out from said first conductive layer to said first low dielectric constant dielectric layer;
a second low dielectric constant dielectric layer, said second low dielectric constant dielectric layer being located on said first low dielectric constant dielectric layer to isolate said first conductive layer;
wherein said first conductive layer and said first dielectric barrier cap have a first gap;
wherein said first low dielectric constant dielectric layer has a second gap which connects to said first gap, inside of said second gap and said first gap communicating with each other;
wherein said second low dielectric constant dielectric layer has a third gap which connects to said second gap, inside of said second gap and said third gap communicating with each other, said first gap, said second gap, and said third gap being combined to become a shape of said dual damascene via;
a second conductive layer, said conductive layer being located in said first gap, said second gap, and said third gap to form said dual damascene via to connect said first conductive layer;
a second barrier layer, said second barrier layer being located on a sidewall of said first gap, said second gap, and said third gap, and at a partial bottom of said third gap to prevent a second ion which is in said second conductive layer moving out from said second conductive layer to said first low dielectric constant dielectric layer and said second low dielectric constant dielectric layer; and
a second dielectric barrier cap, said second dielectric barrier cap being located on said second low dielectric constant dielectric layer, said second barrier layer, and said conductive layer to isolate said second conductive layer.

2. The means according to claim 1, wherein said first conductive layer is an aluminum.

3. The means according to claim 1, wherein said first conductive layer is a copper.

4. The means according to claim 1, wherein said first conductive layer is an aluminum alloy.

5. The means according to claim 1, wherein said first conductive layer is a copper alloy.

6. The means according to claim 1, wherein said second conductive layer is an aluminum.

7. The means according to claim 1, wherein said second conductive layer is a copper.

8. The means according to claim 1, wherein said second conductive layer is an aluminum alloy.

9. The means according to claim 1, wherein said second conductive layer is a copper alloy.

10. The means according to claim 1, wherein said first dielectric barrier cap is a silicon nitride.

11. The means according to claim 1, wherein said second dielectric barrier cap is a silicon carbonic.

12. The means according to claim 1, wherein said second barrier layer comprises a tantalum.

13. The means according to claim 1, wherein said second barrier layer comprises a tantalum nitride.

14. The means according to claim 1, wherein said second barrier layer comprises a titanium nitride.

15. The means according to claim 1, wherein a interface between said bottom of said first gap and said first conductive layer is a tantalum

16. a means of a dual damascene via, said structure comprises:
a first conductive layer, said conductive layer being located in a substrate;
a first barrier layer, said first barrier layer being located on a sidewall and a bottom of said first conductive layer to prevent a first ion which is in said first conductive layer moving out from said first conductive layer;
a first low dielectric constant dielectric layer, said first low dielectric constant dielectric layer being located on said substrate, said first barrier layer, and said first conductive layer to isolate said first conductive layer;
a first dielectric barrier cap, said first dielectric barrier cap being located at said first low dielectric constant dielectric layer to prevent said first ion which is in said first conductive layer moving out from said first conductive layer to said first low dielectric constant dielectric layer;
a second low dielectric constant dielectric layer, said second low dielectric constant dielectric layer being located on said first low dielectric constant dielectric layer to isolate said first conductive layer;
a stop layer; said stop layer being located between said first low dielectric constant dielectric layer and said second low dielectric constant dielectric layer to determine a etching degree in a etching process;
wherein said first conductive layer and said first dielectric barrier cap have a first gap;
wherein said first low dielectric constant dielectric layer has a second gap which connects to said first gap, inside of said second gap and said first gap communicating with each other;
wherein said second low dielectric constant dielectric layer has a third gap which connects to said second gap, inside of said second gap and said third gap communicating with each other, said first gap, said second gap, and said third gap being combined to become a shape of said dual damascene via;
a second conductive layer, said conductive layer being located in said first gap, said second gap, and said third gap to form said dual damascene via to connect said first conductive layer;
a second barrier layer, said second barrier layer being located on a sidewall of said first gap, said second gap, and said third gap, at a partial bottom of said third gap, and at a bottom of said first gap to prevent a second ion which is in said second conductive layer moving out from said second conductive layer to said first low dielectric constant dielectric layer and said second low dielectric constant dielectric layer; and
a second dielectric barrier cap, said second dielectric barrier cap being located on said second low dielectric constant dielectric layer, said second barrier layer, and said conductive layer to isolate said second conductive layer.

17. The means according to claim 16, wherein said first conductive layer is an aluminum.

18. The means according to claim 16, wherein said first conductive layer is an aluminum alloy.

19. The means according to claim 16, wherein said first conductive layer is a copper.

20. The means according to claim 16, wherein said first conductive layer is a copper alloy.

21. The means according to claim 16, wherein said second conductive layer is an aluminum.

22. The means according to claim 16, wherein said second conductive layer is an aluminum alloy.

23. The means according to claim 16, wherein said second conductive layer is a copper.

24. The means according to claim 16, wherein said second conductive layer is a copper alloy.

25. The means according to claim 16, wherein said second dielectric barrier cap is a silicon nitride.

26. The means according to claim 16, wherein said first dielectric barrier cap is a silicon carbonic.

27. The means according to claim 16, wherein said second barrier layer comprises a tantalum.

28. The means according to claim 16, wherein said second barrier layer comprises a tantalum nitride.

29. The means according to claim 16, wherein said second barrier layer comprises a titanium nitride.

30. The means according to claim 16, wherein said stop layer is a silicon nitride.

31. The means according to claim 16, wherein said stop layer is a silicon carbonic.

32. The means according to claim 16, wherein said stop layer is a silicon oxynitride.

33. The means according to claim 16, wherein a depth of said third gap in said first conductive layer is about 100 to 2000 angstroms.

34. a means of a dual damascene via, said structure comprises:
a first conductive layer, said conductive layer being located in a substrate;
a first barrier layer, said first barrier layer being located on a sidewall and a bottom of said first conductive layer to prevent a first ion which is in said first conductive layer moving out from said first conductive layer;
a first low dielectric constant dielectric layer, said first low dielectric constant dielectric layer being located on said substrate, said first barrier layer, and said first conductive layer to isolate said first conductive layer;
a first dielectric barrier cap, said first dielectric barrier cap being located at said first low dielectric constant dielectric layer to prevent said first ion which is in said first conductive layer moving out from said first conductive layer to said first low dielectric constant dielectric layer;
a second low dielectric constant dielectric layer, said second low dielectric constant dielectric layer being located on said first low dielectric constant dielectric layer to isolate said first conductive layer;
a stop layer; said stop layer being located between said first low dielectric constant dielectric layer and said second low dielectric constant dielectric layer to determine a etching degree in a etching process;
wherein said first conductive layer and said first dielectric barrier cap have a first gap;
wherein said first low dielectric constant dielectric layer has a second gap which connects to said first gap, inside of said second gap and said first gap communicating with each other;
wherein said second low dielectric constant dielectric layer has a third gap which connects to said second gap, inside of said second gap and said third gap communicating with each other, said first gap, said second gap, and said third gap being combined to become a shape of said dual damascene via;
a second conductive layer, said conductive layer being located in said first gap, said second gap, and said third gap to form said dual damascene via to connect said first conductive layer;
a second barrier layer, said second barrier layer being located on a sidewall of said first gap, said second gap, and said third gap, at a partial bottom of said third gap, and at a bottom of said first gap to prevent a second ion which is in said second conductive layer moving out from said second conductive layer to said first low dielectric constant dielectric layer and said second low dielectric constant dielectric layer;
a third barrier layer, said third barrier layer being located on said sidewall of said first gap, said second gap, and said third gap, at said partial bottom of said third gap, and at said bottom of said first gap, said third barrier being also located between said second conductive layer and said second barrier layer to increase a adhesion force between said second conductive layer and said second barrier layer;
a second dielectric barrier cap, said second dielectric barrier cap being located on said second low dielectric constant dielectric layer, said second barrier layer, and said conductive layer to isolate said second conductive layer.

35. The means according to claim 34, wherein said first conductive layer is an aluminum.

36. The means according to claim 34, wherein said first conductive layer is an aluminum alloy.

37. The means according to claim 34, wherein said first conductive layer is a copper.

38. The means according to claim 34, wherein said first conductive layer is a copper alloy.

39. The means according to claim 34, wherein said second conductive layer is an aluminum.

40. The means according to claim 34, wherein said second 5 conductive layer is an aluminum alloy.

41. The means according to claim 34, wherein said second conductive layer is a copper.

42. The means according to claim 34, wherein said second conductive layer is a copper alloy.

43. The means according to claim 34, wherein said first dielectric barrier cap is a silicon nitride.

44. The means according to claim 34, wherein said second dielectric barrier cap is a silicon carbonic.

45. The means according to claim 34, wherein said second barrier layer comprises a tantalum.

46. The means according to claim 34, wherein said second barrier layer comprises a tantalum nitride.

47. The means according to claim 34, wherein said second barrier layer comprises a titanium nitride.

48. The means according to claim 34, wherein said stop layer is a silicon nitride.

49. The means according to claim 34, wherein said stop layer is a silicon carbonic.

50. The means according to claim 34, wherein said stop layer is a silicon oxynitride.

51. The means according to claim 34, wherein a depth of said third gap in said first conductive layer is about 100 to 2000 angstroms.

52. The means according to claim 34, wherein said second barrier layer is a tantalum.

53. a means of a dual damascene via, said structure comprises:
a first conductive layer, said conductive layer being located in a substrate;
a first barrier layer, said first barrier layer being located on a sidewall and a bottom of said first conductive layer to prevent a first ion which is in said first conductive layer moving out from said first conductive layer;
a first low dielectric constant dielectric layer, said first low dielectric constant dielectric layer being located on said substrate, said first barrier layer, and said first conductive layer to isolate said first conductive layer;
a first dielectric barrier cap, said first dielectric barrier cap being located at said first low dielectric constant dielectric layer to prevent said first ion which is in said first conductive layer moving out from said first conductive layer to said first low dielectric constant dielectric layer;
a second low dielectric constant dielectric layer, said second low dielectric constant dielectric layer being located on said first low dielectric constant dielectric layer to isolate said first conductive layer;
a stop layer; said stop layer being located between said first low dielectric constant dielectric layer and said second low dielectric constant dielectric layer to determine a etching degree in a etching process;
wherein said first conductive layer and said first dielectric barrier cap have a first gap;
wherein said first low dielectric constant dielectric layer has a second gap which connects to said first gap, inside of said second gap and said first gap communicating with each other;
wherein said second low dielectric constant dielectric layer has a third gap which connects to said second gap, inside of said second gap and said third gap communicating with each other, said first gap, said second gap, and said third gap being combined to become a shape of said dual damascene via;
a second conductive layer, said conductive layer being located in said first gap, said second gap, and said third gap to form said dual damascene via to connect said first conductive layer;
a second barrier layer, said second barrier layer being located on a sidewall of said first gap, said second gap, and said third gap, and at a partial bottom of said third gap to prevent a second ion which is in said second conductive layer moving out from said second conductive layer to said first low dielectric constant dielectric layer and said second low dielectric constant dielectric layer;
a third barrier layer, said third barrier layer being located on said sidewall of said first gap, said second gap, and said third gap, at said partial bottom of said third gap, and at a bottom of said first gap, said third barrier being also located between said second conductive layer and said second barrier layer to increase a adhesion force between said second conductive layer and said second barrier layer;
a second dielectric barrier cap, said second dielectric barrier cap being located on said second low dielectric constant dielectric layer, said second barrier layer, and said conductive layer to isolate said second conductive layer.

54. The means according to claim 53, wherein said first conductive layer is an aluminum.

55. The means according to claim 53, wherein said first conductive layer is an aluminum alloy.

56. The means according to claim 53, wherein said first conductive layer is a copper.

57. The means according to claim 53, wherein said first conductive layer is a copper alloy.

58. The means according to claim 53, wherein said second conductive layer is an aluminum.

59. The means according to claim 53, wherein said second conductive layer is an aluminum alloy.

60. The means according to claim 53, wherein said second conductive layer is a copper.

61. The means according to claim 53, wherein said second conductive layer is a copper alloy.

62. The means according to claim 53, wherein said first dielectric barrier cap is a silicon nitride.

63. The means according to claim 53, wherein said second dielectric barrier cap is a silicon carbonic.

64. The means according to claim 53, wherein said second barrier layer comprises a tantalum.

65. The means according to claim 53, wherein said second barrier layer comprises a tantalum nitride.

66. The means according to claim 53, wherein said second barrier layer comprises a titanium nitride.

67. The means according to claim 53, wherein said stop layer is a silicon nitride.

68. The means according to claim 53, wherein said stop layer is a silicon carbonic.

69. The means according to claim 53, wherein said stop layer is a silicon oxynitride.

70. The means according to claim 53, wherein a depth of said third gap in said first conductive layer is about 100 to 2000 angstroms.

71. The means according to claim 53, wherein said second barrier layer is a tantalum.

72. The means according to claim 53, wherein said bottom of said first gap comprises said second barrier layer.
